(19) United States
(12) Patent Application Publication
(10) Pub. No.: US 2004/0022959 A1
(43) Pub. Date: Feb. 5, 2004

(54) Method of marking substandard parts

(76) Inventors: Knut Kahlisch, Dresden (DE); Henning Mieth, Jahnsdorg (DE); Rudiger Uhlmann, Dresden (DE)

Correspondence Address: BAKER & BOTTS, 30 ROCKEFELLER PLAZA, NEW YORK, NY, 10112

(21) Appl. No.: 10/438,707

(22) Filed: May 15, 2003

(30) Foreign Application Priority Data
May 15, 2002 (DE) 102 21 778.5

(51) Int. Cl. C08J 7/04; B41J 2/435; H01L 23/544; H01L 21/48

(52) U.S. Cl. 427/511; 347/224; 257/797; 438/106

(57) ABSTRACT

The invention relates to a method of marking substandard parts on system carriers for chip mounting. The invention is intended to provide a method of marking substandard parts in which, without special effort, a permanent marking that can easily be detected by an optical recognition system and having adequate contrast can be produced, and in which the occurrence of the stamp effect is reliably avoided. According to the invention, for the marking of substandard parts on the system carrier, use is made of a permanent, non-detachable BUM marking the appearance of which is distinct from the surrounds. This can be carried out by removing material from the surface of the system carrier or by means of a deposition method. Other possibilities exist by means of applying heat at a point or chemical marking. so that a locally limited, permanent appearance, e.g. color change of the substrate close to the surface or of the metal deposited on the said substrate is effected in the area of the BUM marking.

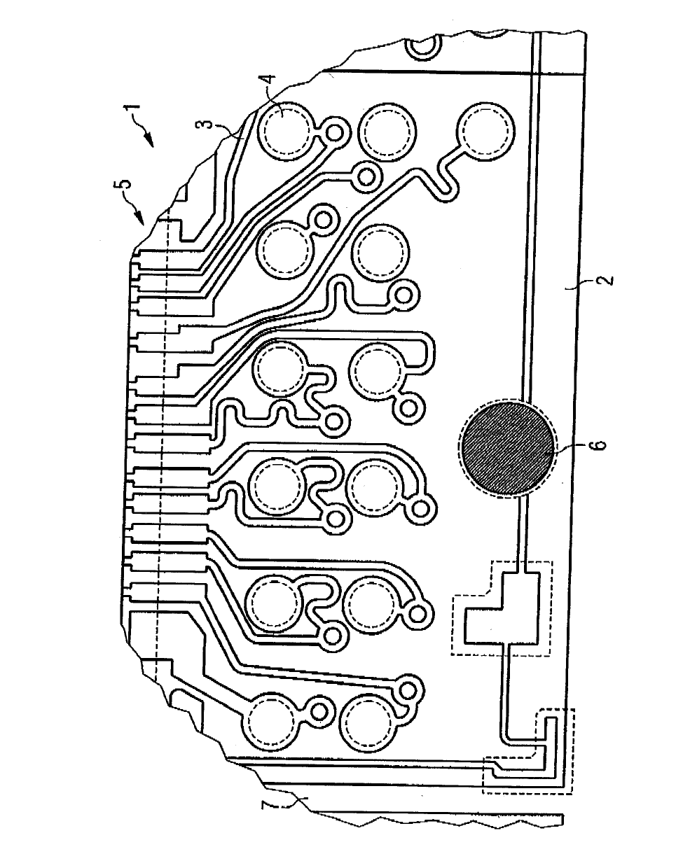

### BACKGROUND OF THE INVENTION

In the production of “Fine Ball Grid Array” (FBGA”) modules, matrix substrates, made for example of glass-fiber-reinforced polymers, are used as system carriers. In this context, a matrix substrate is to be understood to mean that a large number of units to accommodate chips are arranged in the form of a matrix on the system carrier made of a glass-fiber-reinforced polymer (substrate). Because of the particularly high quality requirements, 100% of these units have to be inspected by the manufacturer.

Faulty parts, i.e., substandard parts, are usually identified with a special colored pen at a defined point (gold-coated copper) with a “Bad Unit Marking” or “BUM” marking. In this manner, substandard parts are excluded from further processing during the manufacture of the FBGA components, for example “Chip on Board” (“COB”) components. Chip losses resulting from mounting good chips on substandard parts can thus be avoided by means of these colored markings, which can be detected by a chip bonder.

However, in using this method it is disadvantageous for the colored markings applied by the colored pen to be higher than the surrounding substrate. As result of the necessary process configuration, in particular as a result of the temperature influence during die bonding (chip bonding), it is possible for a color transfer to the chip bonding tool to occur and for the color of the colored marking to be transferred to good parts by the chip bonding tool (stamp effect). Generally, it can be determined that the stamp effect is possible wherever marked substandard parts come into contact with temperature-controlled contact surfaces of the tools needed for the processing. The stamp effect can thus also occur during the molding process. These good parts, unintentionally marked as a faulty, are accordingly excluded from further processing, which ultimately leads to an additional loss of yield even if within an acceptable percentage range.

Attempts have been made to solve the stamp effect problem primarily by means of displacing the marking or by changing the design of the marking. However, due to increasing miniaturization this has been found effective only to a limited extent. Another possible approach to the problem would be to vary the chip mounting conditions (e.g. lower pressing force, temperature). However, this subsequently leads to critical problems in relation to the reduction in the chip adhesion, delamination and reliability problems. Accordingly, after die bonding and molding (encapsulation of the chips, or at least production of a chip edge protector), the system carriers must be separated mechanically.

### SUMMARY OF THE INVENTION

The present invention is based on the object of providing a method of marking substandard parts in which, and without special effort, a permanent marking that can easily be detected by an optical detection system and with adequate contrast is produced, and whereby the occurrence of any stamp effect is reliably avoided. This object is achieved by the marking of substandard parts on the system carrier, using a permanent, non-detachable BUM marking having a color that is distinct from its surroundings. Such permanent marking of substandard parts can be effected with a temperature-resistant color, or else with an ink provided for wafer applications.

Alternatively, the BUM marking can be implemented by removing material from the surface of the matrix substrate, which can be carried out, for example, by means of material-removing machining. Suitable examples of such include the use of milling, drilling, grinding, laser machining or spark erosion.

In another embodiment of the present invention, the BUM marking of substandard parts may be carried out by means of a deposition method, e.g. by metal being deposited on the substandard part. An example of this is the use of a solder material which is deposited on the substandard part, and which results in a permanent marking.

In a further embodiment of the present invention, the BUM marking of substandard parts may be carried out by means of introducing heat at a desired point, so that at least a permanent color change of the substrate close to the surface or of the metal deposited on the said substrate is effected in the area of the BUM marking. The introduction of heat at such a point can be carried out in the simplest case by means of a gas flame, or else by means of a laser beam.

In yet a further embodiment of the present invention, the introduction of heat at a desired point is carried out until at least the topmost material layer in the area of the BUM marking is at least partly detached. The particles produced in the process can be removed without difficulty my means of vacuum extraction.

In a special embodiment of the invention for the marking of substandard parts on the system carrier, a surface, having a limited area is changed by applying a small quantity of a reagent thereto. This can be carried out simply on a Cu pad of a substandard part which is changed chemically by the reagent. In this case, the reagent can be an oxidizing or reducing agent. However, the application of a reducing agent is expedient only when all the areas which are envisaged for the BUM marking have previously been oxidized. As a result, in the case of reduction, the copper surface would then be produced again.

Another embodiment of the invention, comprises marking substandard parts by use of a complex former. For example if NH₃ is used as a complex former, an intense blue Cu tetrammonium complex is produced. In this manner a contrast-rich distinction between good and substandard parts is made possible, so that by using existing image recognition systems of the chip bonders, an unambiguous classification of the FBGA matrix substrates is achieved.

A further advantage of the present invention consists in the fact that reworking of the substandard part is now also possible since the stamp effect is completely avoided.

### BRIEF DESCRIPTION OF THE DRAWING

The invention is explained in greater detail below using exemplary embodiments and further in connection with the drawing in which the FIGURE illustrates a system carrier of an FBGA component with a BUM marking according to the invention.

### DETAILED DESCRIPTION OF THE INVENTION

The FBGA component 1 comprises a system carrier 2, on which are conductor tracks 3, which connect contact areas 4 on the system carrier to a terminal strip 5. Also illustrated in the Figure is the applicable BUM marking 6 of a substandard part, which is a component of a matrix substrate. In the Figure, the dividing lines 7 from the adjacent system carrier 2 are also indicated.

For the marking of substandard parts on the matrix substrate, according to the invention a permanent, non-detachable BUM marking 6 having a color distinct from the surroundings may be used. It is also possible for a temperature-resistant color to be used. A temperature-resistant color is, for example, an ink which is actually used for wafer applications

It is also possible to produce the BUM marking 6 by removing material from the surface of the system carrier 2, which can be carried out, for example, by material-removing machining by means of milling, drilling, grinding, laser machining or spark erosion.

Material deposition methods can also be used for the BUM marking 6 of substandard parts. An example of this is the deposition of a metal, e.g. a solder metal marking 6 on the substandard part.

In a particular exemplary embodiment of the present invention, the BUM marking 6 a of substandard part on the system carrier may be performed by means of the introduction of heat at a particular point, as a result of which a locally limited, permanent color change of the substrate close to the surface, or of the metal deposited on the said substrate, is effected in the area of the BUM marking 6. The introduction of heat at such a point can be carried out by means of a gas flame or else by means of laser energy, until at least the topmost material layer in the region of the BUM marking 6 is at least partly detached. It is desirable to remove any particles which may possibly be produced during this BUM marking procedure.

Furthermore, it is possible to effect a marking of a substandard part on the system carrier 2 on a small surface area by applying a small quantity of a reagent to the desired location. For example, a Cu pad of a substandard part can be contacted with a reagent such as an oxidizing or reducing agent. However, a reducing agent will only be effective if applied when the area envisaged for the BUM marking has previously been oxidized. The result of a reduction would be a pure Cu surface.

Finally, there is also the possibility of using a complex former for the marking of a substandard part. If NH₃ is used as the complex former, an intense blue Cu tetrammonium complex is formed. Where a substandard part is chemically marked, it is necessary that the area or areas which are intended for the BUM marking 6 are not also gold-plated. In the absence of gold plating the chemical conversion of the copper is possible by using the Cu surface, even on a good part, the BUM marking can even be detected on the finished product, as opposed to other substandard part markings.

I claim:

1. A method of marking a substandard part on a system carrier for chip mounting, comprising marking the substandard part with a permanent, non-detachable marking having an appearance which is distinct from its surroundings.

2. A method according to claim 1, further comprising using a temperature-resistant color material to make the marking.

3. A method according to claim 2, wherein the marking is made with an ink used for wafer applications.

4. A method according to claim 1, further comprising removing material from the surface of the system carrier to create the marking.

5. A method according to claim 4, wherein the removal of material is carried out by means of material-removing machining.

6. A method according to claim 5, wherein the material-removing machining is effected by a method selected from the group consisting of milling, drilling, grinding, laser machining or spark erosion.

7. A method according to claim 1, further comprising depositing a material on the substandard part to produce a marking.

8. A method according to claim 7, wherein a metal is deposited to produce the marking.

9. A method according to claim 8, wherein a solder material is deposited.

10. A method according to claim 1, further comprising introducing heat at a point on the substandard part to provide a locally limited, permanent color change to provide the marking.

11. A method according to claim 10, wherein heat is introduced by means of a gas flame.

12. A method according to claim 10, wherein heat is introduced by means of laser energy.

13. A method according to claim 10, wherein heat is introduced until at least a part of a material layer in the area for the marking has at least partly detached.

14. A method according to claims 1, further comprising removing any particles which may be produced during marking.

15. A method according to claim 1, further comprising applying a chemical reagent to a limited surface of a substandard part to effect a change in the appearance of the surface.

16. A method according to claim 15, wherein the reagent is applied to a Cu pad of a substandard part.

17. A method according to claim 15, wherein the reagent is selected from the group consisting of an oxidizing or reducing agent.

18. A method according to claim 1, further comprising marking a substandard part on the system carrier by use of a chemical complex former.

19. A method according to claim 16, wherein NH₃ is used as the complex former.
